(19) United States
(12) Patent Application Publication
(10) Pub. No.: US 2025/0359148 A1
(43) Pub. Date: Nov. 20, 2025

(54) TRIMMED CHANNEL NANOSHEETS WITH DIRECT BACKSIDE CONTACTS

(71) Applicant: INTERNATIONAL BUSINESS MACHINES CORPORATION, ARMONK, NY (US)

(72) Inventors: GIDEON OYIBO, Rensselaer, NY (US); Tao Li, Slingerlands, NY (US); Ruilong Xie, Niskayuna, NY (US); Nicolas Jean Loubet, GUILDERLAND, NY (US)

(21) Appl. No.: 18/668,837

(22) Filed: May 20, 2024

(51) Int. Cl. H01L 29/417; H01L 23/528; H01L 29/06; H01L 29/40; H01L 29/423; H01L 29/66; H01L 29/775; H01L 29/786

(52) U.S. Cl. CPC H10D 30/6729; H01L 23/5286; H10D 30/014; H10D 30/031; H10D 30/43; H10D 30/6735; H10D 30/6757; H10D 62/121; H10D 64/01; H10D 64/017

(57) ABSTRACT

A nanosheet semiconductor structure including a plurality of channel nanosheets arranged one above another and each surrounded by a gate structure, where a width of each channel region of the plurality of channel nanosheets varies across its length.

### BACKGROUND

The present invention generally relates to semiconductor structures, and more particularly to nanosheet transistor structures having trimmed channel nanosheets with direct backside contacts.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a plurality of channel nanosheets arranged one above another and each surrounded by a gate structure, where a width of each channel region of the plurality of channel nanosheets varies across its length.

According to another embodiment of the present invention, a semiconductor structure is provided. The semiconductor structure may include a plurality of channel nanosheets arranged one above another and each surrounded by a gate structure, where each channel region of the plurality of channel nanosheets comprises a first thickness and a second thickness, and where the first thickness is greater than the second thickness;

According to another embodiment of the present invention, a semiconductor structure is provided. The semiconductor structure may include a plurality of channel nanosheets arranged one above another and each surrounded by a gate structure, where each channel region of the plurality of channel nanosheets comprises a middle portion and end portions, where a thickness of the middle portion is less than a thickness of the end portions, and where a width of the middle portion is less than a width of the end portions.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating nanosheet transistor structures according to an exemplary embodiment;

FIGS. 5, 6, and 7 are cross-sectional views of the semiconductor structure after selectively removing the sacrificial gates and the and the sacrificial nanosheets according to an exemplary embodiment;

FIGS. 8, 9, and 10 are cross-sectional views of the semiconductor structure after trimming the channel nanosheets according to an exemplary embodiment;

FIGS. 11, 12, and 13 are cross-sectional views of the semiconductor structure after forming gate structures, middle-of-line, back-end-of-line, and securing a carrier wafer according to an exemplary embodiment;

FIGS. 14, 15, and 16 are cross-sectional views of the semiconductor structure after flipping the assembly and recessing the substrate according to an exemplary embodiment;

FIGS. 17, 18, and 19 are cross-sectional views of the semiconductor structure after removing and recessing remaining portions of the substrate, trimming the placeholders, and forming a backside dielectric layer according to an exemplary embodiment;

FIGS. 20, 21, and 22 are cross-sectional views of the semiconductor structure after forming a mask and removing portions of the backside dielectric layer to form backside contact trenches according to an exemplary embodiment; and

FIGS. 23, 24, and 25 are cross-sectional views of the semiconductor structure after removing the placeholders and forming backside contact structures according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating channel nanosheets with reduce dimensions (eg width) with direct backside contacts to the source drain presents unique challenges. More specifically, for example, employing conventional placeholder fabrication and backside contact techniques with reduced channel nanosheet widths results in excessive placeholder erosion during subsequent removable of the substrate. The excessive placeholder erosion results in backside contacts having reduces cross-sectional dimensions thereby causing undesirable increases in contact resistance.

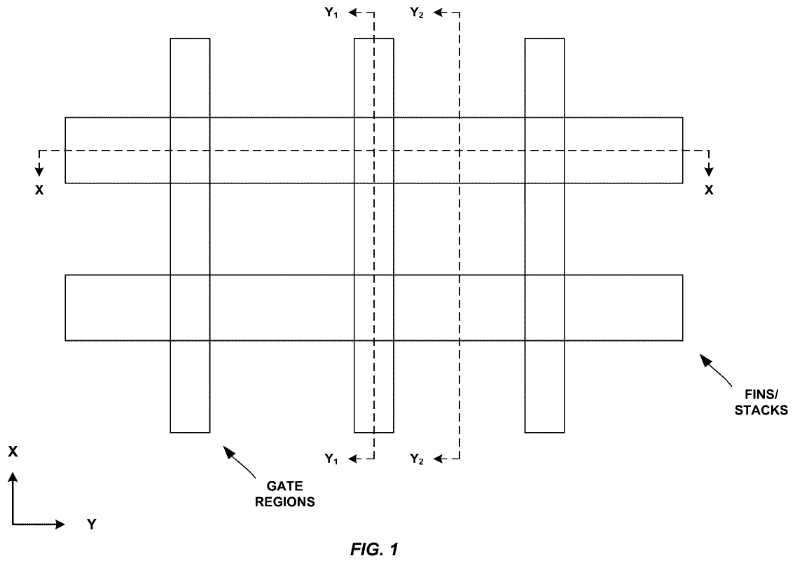

The present invention generally relates to semiconductor structures, and more particularly to nanosheet transistor structures having trimmed channel nanosheets with direct backside contacts. More specifically, the nanosheet transistor structures and associated method disclosed herein enable a novel solution for providing nanosheet transistor structures having trimmed channel nanosheets with direct backside contacts. Exemplary embodiments of nanosheet transistor structures having trimmed channel nanosheets with direct backside contacts are described in detail below by referring to the accompanying drawings in FIGS. 1 to 25. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-25 represent cross section views oriented as indicated in FIG. 1

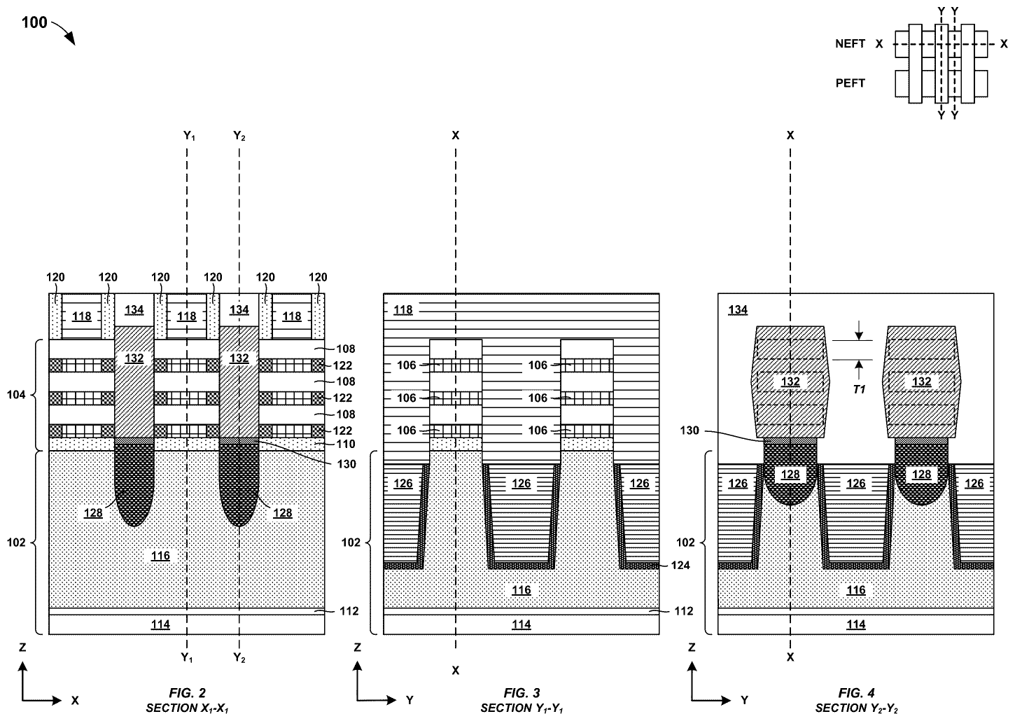

Referring now to FIGS. 2, 3, and 4, a structure 100 is shown during an intermediate step of a method of fabricating a nanosheet transistor structure according to an embodiment of the invention. FIG. 2 depicts a cross-sectional view of the structure 100 taken along line X₁-X₁, FIG. 3 depicts a cross-sectional view of the structure 100 taken along line Y₁-Y₁, and FIG. 3 depicts a cross-sectional view of the structure 100 shown taken along line Y₂-Y₂.

The structure 100 illustrated in FIGS. 2-4 includes an array of nanosheet transistors formed on a substrate 102 in accordance with known techniques. As illustrated, the array of nanosheet transistors includes nanosheet stacks 104. Each nanosheet stack 104 includes an alternating series of silicon germanium (SiGe) sacrificial nanosheets 106 (hereinafter “sacrificial nanosheets 106”), silicon (Si) channel nanosheets 108 (hereinafter “channel nanosheets 108”), and a dielectric spacer material (hereinafter “stack spacers 110”), as illustrated.

According to embodiments of the present disclosure, the sacrificial nanosheets 106 are intentionally thinner than comparable structures, and the channel nanosheets 108 are intentionally thicker than comparable structures. For example, the sacrificial nanosheets 106 and the channel nanosheets 108 of comparable structures may be approximately the same thickness; however, in the present embodiment the channel nanosheets 108 are thicker than the sacrificial nanosheets 106. More specifically, according to disclose embodiments, a thickness (T1) of the channel nanosheets 108 measured in the z-direction ranges from approximately 5 nm to approximately 20 nm, and a thickness of the sacrificial nanosheets 106 measured in the z-direction is less than the thickness (T1) of the channel nanosheets 108. In at least another embodiment, the thickness (T1) of the channel nanosheets 108 is larger than 20 nm.

For purposes of orientation, the substrate 102 is herein referred to as being on a “backside” of the structure 100 and the array of nanosheet transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 112 separates a base substrate 114 from a top semiconductor layer 116. Unlike conventional layered semiconductor substrates, the etch stop layer 112 of the substrate 102 may include any material which affects the desired etch selectivity during subsequent processing. For example, the etch stop layer 112 may be a conventional buried oxide layer, or it may be a silicon germanium layer with a specific germanium concentration. In practice, the etch stop layer 112 will function as an etch stop layer and can be composed of any material which supports that function.

In the present embodiment, both the base substrate 114 and the top semiconductor layer 116 may be any bulk substrate made from any of several known semiconductor materials such as, for example, silicon, germanium, silicon-germanium alloy, and compound (e.g. III-V and II-VI) semiconductor materials. For example, both the base substrate 114 and the top semiconductor layer 116 may be made from silicon. Additionally, both the etch stop layer 112 and the base substrate 114 are sacrificial and will not remain in the final structure. As such, thickness of the top semiconductor layer 116, and similarly the position of the etch stop layer 112, approximately denote a relative position of subsequently formed backside features, such as, backside wiring layers or a backside power delivery network.

In one or more embodiments, the nanosheet stacks 104 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, in at least one embodiment, the channel nanosheets 108 are doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

The stack spacers 110 are formed beneath the nanosheet stacks 104 according to known techniques. Specifically, for example, a silicon germanium layer would be initially formed beneath the other layers of the nanosheet stacks 104, and then subsequently replaced with a suitable dielectric material. In some embodiments, for example, the stack spacers 110 may be composed of SiN, SiBCN, SiOCN, SiOC, or any other combination of low-k materials. The term “low-k” as used throughout the present application denotes a dielectric material that has a dielectric constant of less than 4.0. According to embodiments of the present disclosure, the stack spacers 110 function to isolate the nanosheet stacks 104 from the substrate 102.

The structure 100 further includes sacrificial gates 118, gate spacers 120, and inner spacers 122, as illustrated.

The sacrificial gates 118 are formed perpendicular to the nanosheet stacks 104 according to known techniques. Specifically, for example, a relatively thick layer of amorphous silicon is blanket deposited and subsequently patterned to form the sacrificial gates 118, as illustrated.

The gate spacers 120 are added to sidewalls of the sacrificial gates 118 and generally define the channel length and the source drain regions, according to known techniques. The gate spacers 120 ultimately electrically insulate subsequently formed gate structures from other surrounding structures, such as, for example, source drain contacts. In at least one embodiment, the gate spacers 120 include silicon nitride, silicon boron nitride, silicon carbon nitride, silicon boron carbon nitride, or other known equivalents.

The inner spacers 122 are disposed between alternate channels (108) in each of the nanosheet stacks 104, and laterally separate subsequently formed gate structures from subsequently formed source drain regions, as illustrated. Only need a relatively small or thin inner spacer to fill the divot. As gate pitch scales, there is less room to accommodate a relatively large or thick inner spacer to fill the divot. Additionally, the inner spacers 122 are positioned such that subsequent etching processes used to remove the sacrificial nanosheets 106 during device fabrication do not also attack the source drain regions. In one or more embodiments, the inner spacers 122 are made from a nitride containing material, for example silicon nitride (SiN).

The structure 100 further includes shallow trench isolation regions (hereinafter “STI regions”) which extend partially into the substrate 102 below the array of nanosheet transistors. In general, the STI regions may each include an isolation liner 124 and an isolation fill 126. For example, the isolation liner 124 is SiN, SiON, or SiOCN, and the isolation fill 126 is silicon oxide (SiO) or silicon nitride (SiN).

The structure 100 further includes placeholders 128, buffer layers 130, and source drain regions 132 generally arranged between adjacent nanosheet stacks 104, as illustrated.

The placeholders 128 are formed by filling self-aligned openings in the top semiconductor layer 116 between adjacent nanosheet stacks 104 with a sacrificial material according to known techniques. Specifically, after filling, the sacrificial material is recessed to create the placeholders 128 according to known techniques. In an embodiment, the sacrificial material is silicon germanium or amorphous silicon epitaxially grown from the surfaces of the top semiconductor layer 116. In another embodiment, the sacrificial material is SiC, SiOC deposited using, for example, chemical vapor deposition (CVD) or plasma enhanced CVD (PECVD) and subsequently recessed using, for example, reactive ion etching (RIE). Other suitable deposition and recessing techniques may be used provided they do not induce a physical or chemical change to the channel nanosheets 108.

The buffer layers 130 are formed on top of the placeholders 128 according to known techniques. Specifically, an etch stop material is formed directly on top of the placeholders 128 to create the buffer layers 130. In an embodiment, the etch stop material can be any silicon-based material suitable to provide needed etch stop properties during backside processing. For example, the buffer layers 130 are designed to allow the subsequent removal of the placeholders 128 selective to the source drain regions 132.

The source drain regions 132 are formed on top of the buffer layers 130 according to known techniques. Specifically, the source drain regions 132 are disposed between adjacent nanosheet stacks 104 in direct contact with exposed ends of the channel nanosheets 108. More specifically, the source drain regions 132 may be epitaxially grown from the exposed ends of the channel nanosheets 108 according to known techniques.

Finally, the structure 100 further includes a dielectric layer 134 directly above and surrounding the source drain regions 132. The dielectric layer 134 is composed of any suitable interlayer dielectric material, such as, for example, oxides such as silicon oxide (SiOₓ), nitrides such as silicon nitride (SiₓN_{y}), and/or low-K materials such as SiCOH or SiBCN. In another embodiment, is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 134. Using a self-planarizing dielectric material as the dielectric layer 134 can avoid the need to perform a subsequent planarizing step. After formation, top surfaces of the dielectric layer 134 are typically made flush, or substantially flush, with top surfaces of the sacrificial gates 118 and the gate spacers 120 by chemical mechanical polishing techniques.

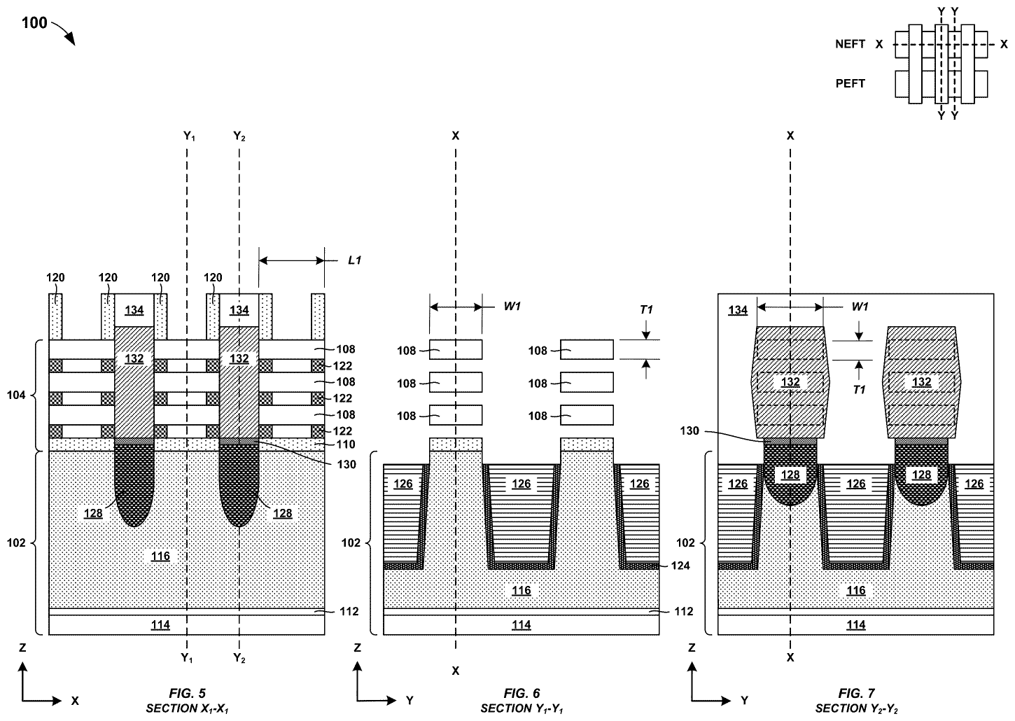

Referring now to FIGS. 5, 6, and 7, the structure 100 is shown after selectively removing the sacrificial gates 118 and the and the sacrificial nanosheets 106 according to an embodiment of the invention. FIG. 5 depicts a cross-sectional view of the structure 100 taken along line X₁-X₁, FIG. 6 depicts a cross-sectional view of the structure 100 taken along line Y₁-Y₁, and FIG. 7 depicts a cross-sectional view of the structure 100 shown taken along line Y₂-Y₂.

The sacrificial gates 118 and the sacrificial nanosheets 106 are selectively removed according to known techniques. First, the sacrificial gates 118 are etched and removed selective to the gate spacers 120 and the nanosheet stacks 104 according to known techniques. Next, the sacrificial nanosheets 106 are etched and removed selective to the channel nanosheets 108 and the inner spacers 122 according to known techniques. Doing so is made possible by the different concentrations of germanium. In this case, the layers with germanium are removed selective to layers without germanium.

With continued reference to FIGS. 5-7, and according to embodiments of the present disclosure, a length (L1) of the channel nanosheets 108 measured in the x-direction (from one source drain region 132 to an adjacent source drain region 132) ranges from approximately 20 nm to approximately 40 nm; a width (W1) of the channel nanosheets 108 measured in the y-direction ranges from approximately 6 nm to approximately 100 nm; and, as noted above, a thickness (T1) of the channel nanosheets 108 measured in the z-direction ranges from approximately 5 nm to approximately 20 nm. It is further noted, due to the nature of fabrication top protruding portions of the top semiconductor layer 116 and the stack spacers 110 will be approximately the same width as the channel nanosheets 108, as illustrated in FIG. 6.

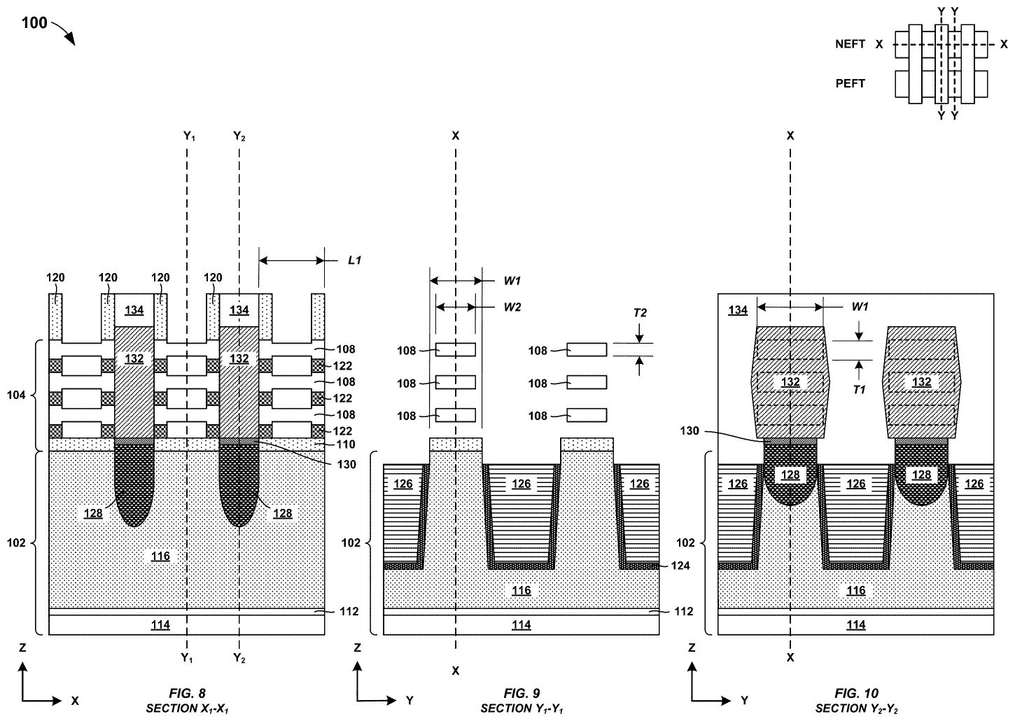

Referring now to FIGS. 8, 9, and 10, the structure 100 is shown after trimming the channel nanosheets 108 according to an embodiment of the invention. FIG. 8 depicts a cross-sectional view of the structure 100 taken along line X₁-X₁, FIG. 9 depicts a cross-sectional view of the structure 100 taken along line Y₁-Y₁, and FIG. 10 depicts a cross-sectional view of the structure 100 shown taken along line Y₂-Y₂.

Exposed portions of the channel nanosheets 108 are trimmed according to known techniques. Specifically, portions of the channel nanosheets 108 are removed selective to the surrounding structure, for example, the gate spacers 120 and the inner spacers 122. The portions of the channel nanosheets 108 can be removed using conventional isotropic dry etch or wet etching techniques. As a result, dimensions the channel nanosheets 108 dimensions are reduced. For example, the thickness of the channel nanosheets 108 is reduced in the z-direction (FIGS. 8 and 9) and a width of the channel nanosheets 108 is reduced in the y-direction (FIG. 9). In all cases, etching is designed or intended to merely trim the exposed portions of the channel nanosheets 108, and not remove them completely. It is further noted, portions of the channel nanosheets 108 which are not exposed, or remain between the inner spacers 122 will not experience the same reduction in width or thickness. Finally, the embodiments disclosed herein explicitly enable reducing the width and thickness of the channel nanosheets 108 after formation of the placeholders 128. Doing so maintains suitable placeholder width thereby eliminating concerns of excessive placeholder erosion during subsequent removable of the substrate 102. By eliminating the excessive placeholder erosion, suitable cross-sectional dimensions of subsequently formed backside contacts can be maintained thereby preventing any undesirable increases in contact resistance.

With continued reference to FIGS. 8-10, and according to embodiments of the present disclosure, a width (W2) of the channel nanosheets 108 measured in the y-direction could be any value in nm less than W1; and a thickness (T2) of the channel nanosheets 108 measured in the z-direction could be any value in nm less than T1. In at least one embodiment, trimming the channel nanosheets 108 continues without reducing either the width (W2) or the thickness (T2) to zero. Furthermore, the dimensions, width (W2) and the thickness (T2), of the channel nanosheets 108 after trimming should be based on desired device operation and performance. It is noted that only the width and thickness of the channel nanosheets 108 are reduced and the length (L1) remains the same after trimming.

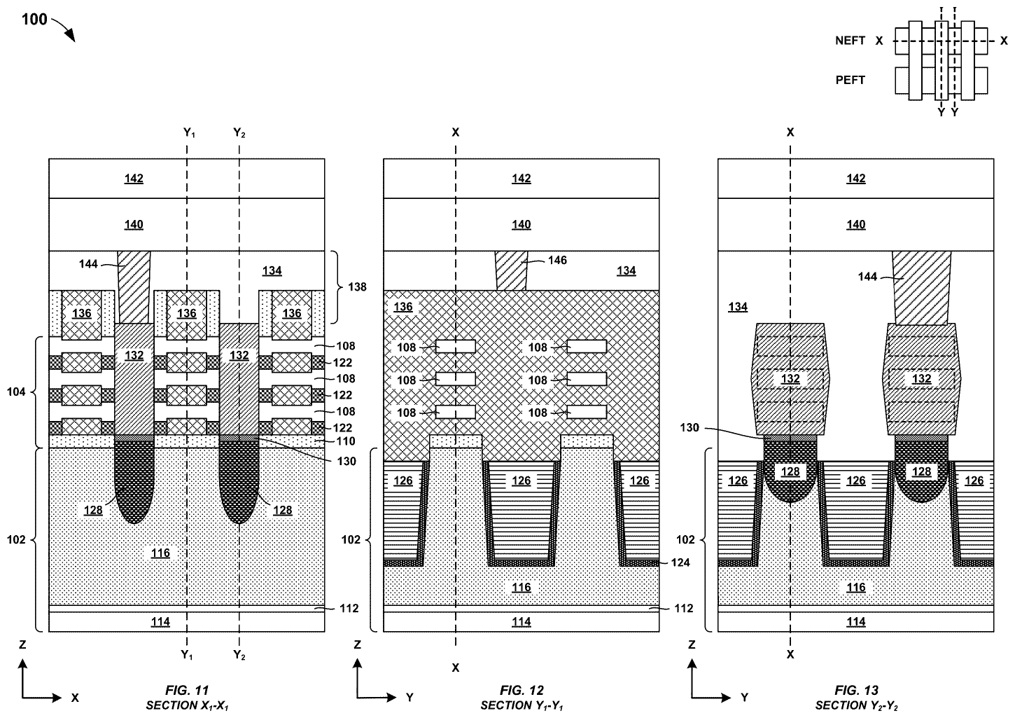

Referring now to FIGS. 11, 12, and 13, the structure 100 is shown after forming gate structures 136, middle-of-line 138, back-end-of-line 140, and securing a carrier wafer 142 according to an embodiment of the invention. FIG. 11 depicts a cross-sectional view of the structure 100 taken along line X₁-X₁, FIG. 12 depicts a cross-sectional view of the structure 100 taken along line Y₁-Y₁, and FIG. 13 depicts a cross-sectional view of the structure 100 shown taken along line Y₂-Y₂.

First, the gate structures 136 are formed according to known techniques. In some embodiments, a gate dielectric (not shown) is first conformally deposited directly on exposed surfaces of the structure 100 within the gate cavities or openings and spaces left by removing the sacrificial gates 118 and the sacrificial nanosheets 106 according to known techniques. For example, the gate dielectric is conformally deposited on exposed surfaces of the channel nanosheets 108 and the inner spacers 122.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, a work function metal is conformally deposited on the gate dielectric formed within the gate cavities according to known techniques. In at least one embodiment, the work function metal is made of the same conductive material across the entire structure. In at least another embodiment, the work function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium carbon (TiC), titanium alumunm (TiAl), titanium aluminum cabron (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, a gate metal or contact metal, is deposited directly on the work function metal, and fills the gate cavities. The gate metal may include any suitable conductive material, such as, for example, copper, ruthenium, aluminum, tungsten, cobalt, or alloys thereof. After, excess conductive material can be polished using known techniques.

Next, additional interlayer dielectric material is deposited according to known techniques. The dielectric layer 134 illustrated in the figures includes the additional interlayer dielectric material.

Next, the middle-of-line 138 is formed according to known techniques. The middle-of-line 138 includes source drain contacts 144 and gate contacts 146 which may be generally referred to as middle-of-line contacts. The source drain contacts 144 and the gate contacts 146 are formed according to known techniques.

Next, the back-end-of-line 140 is formed according to known techniques. The back-end-of-line 140 may include vias and metal lines which may be generally referred to as back-end-of-line interconnects. The vias and the metal lines are formed according to known techniques.

Finally, the carrier wafer 142 is secured to a top of the structure 100 according to an embodiment of the invention. The carrier wafer 142 is attached, or removably secured, to the back-end-of-line 140. In general, and not depicted, the carrier wafer 142 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 142 according to known techniques.

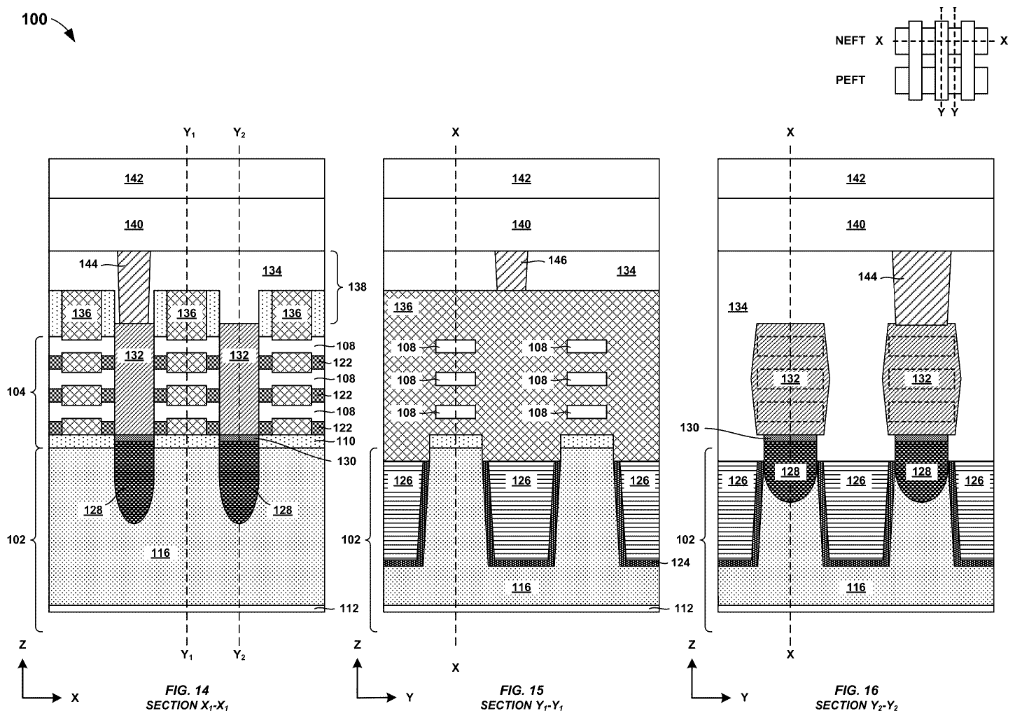

Referring now to FIGS. 14, 15, and 16, the structure 100 is shown after flipping the assembly and recessing the substrate 102 according to an embodiment of the invention. FIG. 14 depicts a cross-sectional view of the structure 100 taken along line X₁-X₁, FIG. 15 depicts a cross-sectional view of the structure 100 taken along line YI-YI, and FIG. 16 depicts a cross-sectional view of the structure 100 shown taken along line Y₂-Y₂.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 114 is recessed or completely removed to expose the etch stop layer 112, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

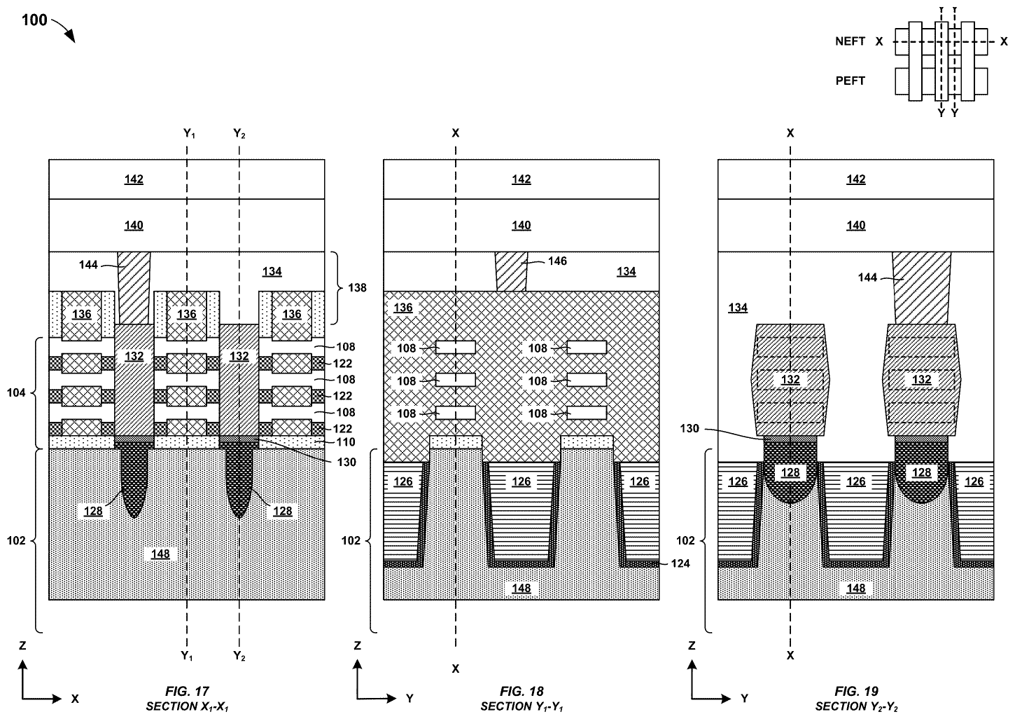

Referring now to FIGS. 17, 18, and 19, the structure 100 is shown after removing and recessing remaining portions of the substrate 102, trimming the placeholders 128, and forming a backside dielectric layer 148 according to an embodiment of the invention. FIG. 17 depicts a cross-sectional view of the structure 100 taken along line X₁-X₁, FIG. 18 depicts a cross-sectional view of the structure 100 taken along line Y₁-Y₁, and FIG. 19 depicts a cross-sectional view of the structure 100 shown taken along line Y₂-Y₂.

First, the etch stop layer 112 is selectively removed and the top semiconductor layer 116 is recessed according to known techniques. Specifically, the etch stop layer 112 is removed selective to the top semiconductor layer 116 and the top semiconductor layer 116 is removed selective to the placeholders 128, the stack spacers 110, the gate structures 136, and the STI regions, as illustrated. As indicated in the figures, some erosion of the placeholders 128 is anticipated to be an unintended consequence resulting from selectively removing the top semiconductor layer 116. Such erosion would normally lead to smaller backside contacts using conventional fabrication techniques. For example, when the placeholder 128 are removed and replaced with the contact material, the resulting backside contact mimic the eroded shape and size of the placeholders 128 which causes undesirable increases in resistance.

Finally, the backside dielectric layer 148 is deposited according to known techniques. Specifically, a backside dielectric material is blanket deposited across the structure 100. The backside dielectric layer 148 completely covers exposed portions of the placeholders 128 and the stack spacers 110. After deposition, known chemical mechanical polishing may be used to remove excess portions of the backside dielectric material from bottom surfaces of the structure 100.

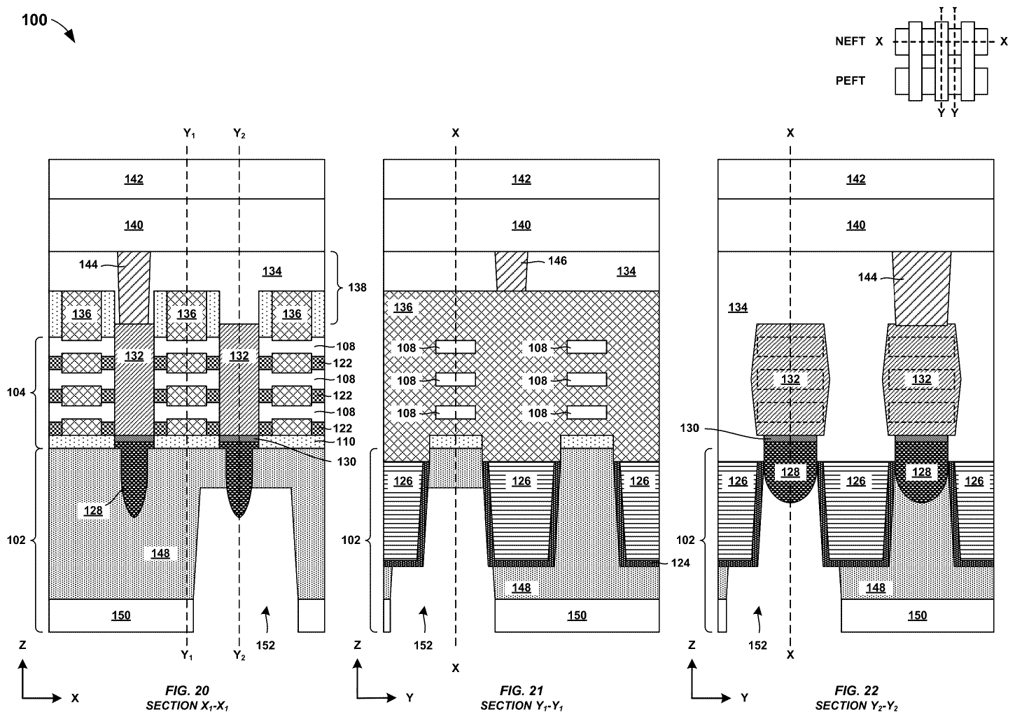

Referring now to FIGS. 20, 21, and 22, the structure 100 is shown after forming a mask 150 and removing portions of the backside dielectric layer 148 to form backside contact trenches 152 according to an embodiment of the invention. FIG. 20 depicts a cross-sectional view of the structure 100 taken along line X₁-X₁, FIG. 21 depicts a cross-sectional view of the structure 100 taken along line Y₁-Y₁, and FIG. 22 depicts a cross-sectional view of the structure 100 shown taken along line Y₂-Y₂.

First, the mask 150 is deposited and subsequently patterned to expose certain portions of the structure 100 according to known techniques. The mask 150 can be an organic planarization layer (OPL) or a layer of material that is capable of being planarized or etched by known techniques. In an embodiment, for example, the mask 150 can be an amorphous carbon layer able to withstand subsequent processing temperatures. The mask 150 can preferably have a thickness sufficient to cover existing structures. After depositing the mask 150, a dry etching technique is applied to pattern or recess the mask 150 according to known techniques. The mask 150 is patterned consistent with a size and a location of subsequently formed backside contact structures. For example, after patterning the mask 150, portions of the structure 100 in contact regions are exposed, as illustrated.

Exposed portions of the backside dielectric layer 148 are then selectively removed to form the backside contact trenches 152 according to known techniques. Specifically, exposed portions of the backside dielectric layer 148 are removed using known etching techniques suitable to remove silicon-based dielectric materials selective to the mask 150, the placeholders 128, and the STI regions, as illustrated. In an embodiment, the exposed portions of the backside dielectric layer 148 are removed using an anisotropic etch such as, for example, reactive ion etching (RIE). After removing the exposed portions of the backside dielectric layer 148, portions of the placeholders 128 and the STI regions are exposed within the backside contact trenches 152, as illustrated. Significant to the embodiments disclosed herein, etching must continue until at least a portion of the placeholders 128 are exposed, for example, as best illustrated in FIG. 20. In such cases, some or all of the backside dielectric layer 148 is completely removed from between adjacent STI regions, as best illustrated in FIG. 22.

Specific to the disclosed embodiments, it is noted that pattern the backside contact trenches 152 is rather forgiving and not susceptible to misalignment or error. Said differently, the backside contact trenches 152 may overlap, or extend beneath, the gate structures 136 without concerns of shorting, as described further below.

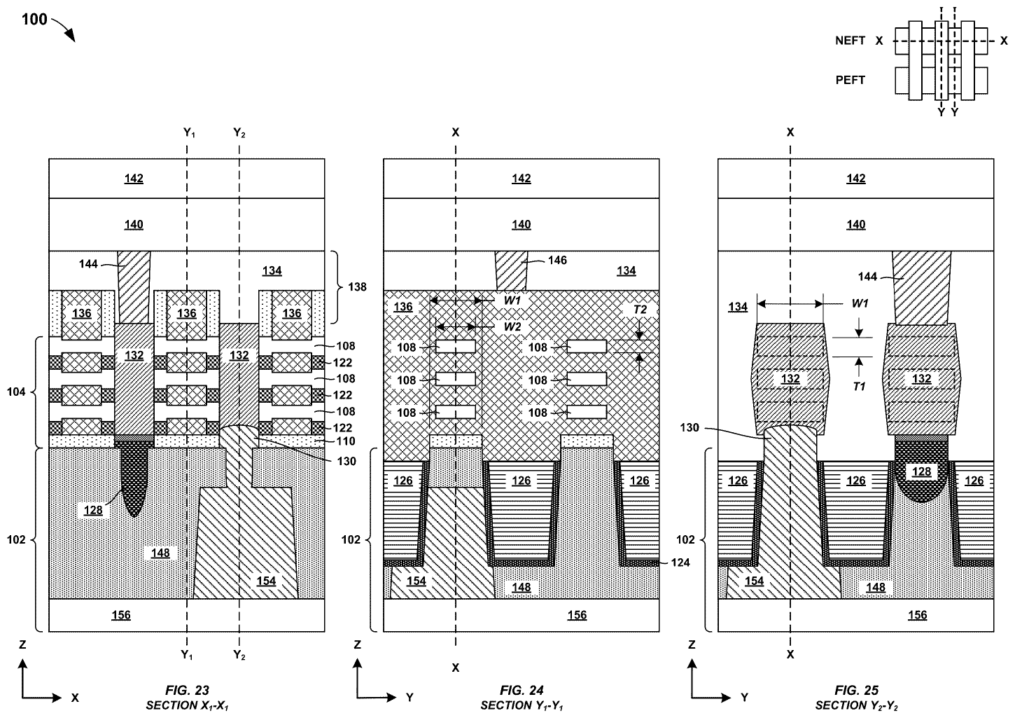

Referring now to FIGS. 23, 24, and 25, the structure 100 is shown after removing the placeholders 128 and forming backside contact structures 154 according to an embodiment of the invention. FIG. 23 depicts a cross-sectional view of the structure 100 taken along line X₁-X₁, FIG. 24 depicts a cross-sectional view of the structure 100 taken along line Y₁-Y₁, and FIG. 25 depicts a cross-sectional view of the structure 100 shown taken along line Y₂-Y₂.

The placeholders 128 exposed within the backside contact trenches 152 are selectively removed according to known techniques. Specifically, the placeholders 128 are etched or removed selective to the backside dielectric layer 148, the stack spacers 110, the STI regions, and the buffer layer 130. The placeholders 128 can be removed using compatible selective dry etching techniques.

In doing so, the backside contact trenches 152 are enlarged or recessed directly beneath the source drain regions 132 without exposing the source drain regions 132 due to the existence of the buffer layers 130. Finally, exposed buffer layers 130 are subsequently removed selective to the surrounding structures according to known techniques. In some cases, some gouging or recessing of the source drain regions 132 may occur, as illustrated.

Next, the backside contact trenches 152 are filled with a conductive material to form the backside contact structures 154 according to known techniques. The backside contact structures 154 may include any suitable conductive material, such as, for example, copper, ruthenium, aluminum, tungsten, cobalt, or alloys thereof. In some embodiments, a metal silicide is formed at the bottom of the backside contact trenches prior to filling them with the conductive material.

After deposition, excess conductive material can be polished using known techniques until bottommost surfaces of the backside contact structures 154 are flush, or substantially flush, with bottommost surfaces of the backside dielectric layer 148, as illustrated. After polishing, bottommost surfaces of the backside contact structures 154 are substantially flat. It is noted, the backside contact structures 154 may include, for example, backside source drain contacts, as illustrated, as well as backside gate contacts (not shown).

After forming the backside contact structures 154, the backside wiring layers 156 are subsequently formed according to known techniques. The backside wiring layers 156 typically include at least backside power rails, a backside power delivery network, or both.

Specific to the disclosed embodiments, it is noted that pattern the backside contact structures 154 overlap, or extend beneath, the gate structures 136 without shorting to the gate structures 136. As illustrated in the figures, the backside contact structures 154 provide electrical connections between the backside wiring layers 156 and the source drain regions 132, and shorting to the gate structures 136 is not part of the design.

According to the embodiment illustrated in FIGS. 23-25, the nanosheet transistor structures represented by the structure 100 have some distinctive and notable features. For instance, the dimensions of the channel nanosheets 108 vary along their length. For purposes of the present disclosure length of the channel nanosheets 108 is measured in the x-direction (or perpendicular to the gate structures 136), width of the channel nanosheets 108 is measured in the y-direction (or parallel to the gate structures 136); and thickness of the channel nanosheets 108 is measured in the z-direction.

After trimming the channel nanosheets 108 may have middle portions distinguishable from end portions. The middle portion of each channel nanosheet 108 is surrounded by the gate structure 136 and the end portions remain surrounded on top and bottom by the inner spacers 122. As such, according to embodiment of the present disclosure, a thickness and a width of the middle portion of each channel nanosheet 108 is smaller than a thickness and a width of the end portions of the channel nanosheet 108.

Further, due to the nature of fabrication top protruding portions of the backside dielectric layer 148 will be approximately the same width (W1) as the stack spacers 110, and the width (W2) of the trimmed channel nanosheets 108 will less than the width (W1) of the stack spacers 110, as illustrated in FIG. 24.

With continued reference to FIGS. 23-25, and according to an embodiment, the structure 100 includes a plurality of channel nanosheets arranged one above another and each surrounded by a gate structure, where a width of each channel region of the plurality of channel nanosheets varies across its length.

With continued reference to FIGS. 23-25, and according to an embodiment, the structure further includes stack spacers below and vertically aligned with the plurality of channel nanosheets, wherein a width of the stack spacers measured in a direction parallel to the gate structure is greater than a width of the plurality of channel nanosheets.

With continued reference to FIGS. 23-25, and according to an embodiment, the structure further includes a backside contact structure self-aligned to shallow trench isolation regions and partially extending beneath the gate structure.

With continued reference to FIGS. 23-25, and according to an embodiment, a length of a portion of the backside contact structure is approximately equal to a length of a source drain region immediately below and directly contacting the backside contact structure.

With continued reference to FIGS. 23-25, and according to an embodiment, the structure further includes a placeholder adjacent to the backside contact structure and directly beneath a source drain region.

With continued reference to FIGS. 23-25, and according to an embodiment, a topmost surface of the backside contact structure is above a topmost surface of the placeholder.

With continued reference to FIGS. 23-25, and according to an embodiment, the structure further includes a buffer layer between and physically separating the placeholder from the source drain region.

With continued reference to FIGS. 23-25, and according to an embodiment, the structure 100 includes a plurality of channel nanosheets arranged one above another and each surrounded by a gate structure, where each channel region of the plurality of channel nanosheets comprises a first thickness and a second thickness, and where the first thickness is greater than the second thickness;

With continued reference to FIGS. 23-25, and according to an embodiment, the structure 100 includes a plurality of channel nanosheets arranged one above another and each surrounded by a gate structure, where each channel region of the plurality of channel nanosheets comprises a middle portion and end portions, where a thickness of the middle portion is less than a thickness of the end portions, and where a width of the middle portion is less than a width of the end portions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A nanosheet semiconductor structure comprising:
a plurality of channel nanosheets arranged one above another and each surrounded by a gate structure, wherein a width of each channel region of the plurality of channel nanosheets varies across its length.

2. The semiconductor structure according to claim 1, further comprising:
stack spacers below and vertically aligned with the plurality of channel nanosheets, wherein a width of the stack spacers measured in a direction parallel to the gate structure is greater than a width of the plurality of channel nanosheets.

3. The semiconductor structure according to claim 1, further comprising:
a backside contact structure self-aligned to shallow trench isolation regions and partially extending beneath the gate structure.

4. The semiconductor structure according to claim 3, wherein a length of a portion of the backside contact structure is approximately equal to a length of a source drain region immediately below and directly contacting the backside contact structure.

5. The semiconductor structure according to claim 3, further comprising:
a placeholder adjacent to the backside contact structure and directly beneath a source drain region.

6. The semiconductor structure according to claim 5, wherein a topmost surface of the backside contact structure is above a topmost surface of the placeholder.

7. The semiconductor structure according to claim 5, further comprising:
a buffer layer between and physically separating the placeholder from the source drain region.

8. A nanosheet semiconductor structure comprising:
a plurality of channel nanosheets arranged one above another and each surrounded by a gate structure, wherein each channel region of the plurality of channel nanosheets comprises a first thickness and a second thickness, and wherein the first thickness is greater than the second thickness.

9. The semiconductor structure according to claim 1, further comprising:
stack spacers below and vertically aligned with the plurality of channel nanosheets, wherein a width of the stack spacers measured in a direction parallel to the gate structure is greater than a width of the plurality of channel nanosheets.

10. The semiconductor structure according to claim 8, further comprising:
a backside contact structure self-aligned to shallow trench isolation regions and partially extending beneath the gate structure.

11. The semiconductor structure according to claim 10, wherein a length of a portion of the backside contact structure is approximately equal to a length of a source drain region immediately below and directly contacting the backside contact structure.

12. The semiconductor structure according to claim 10, further comprising:
a placeholder adjacent to the backside contact structure and directly beneath a source drain region.

13. The semiconductor structure according to claim 12, wherein a topmost surface of the backside contact structure is above a topmost surface of the placeholder.

14. The semiconductor structure according to claim 12, further comprising:
a buffer layer between and physically separating the placeholder from the source drain region.

15. A nanosheet semiconductor structure comprising:
a plurality of channel nanosheets arranged one above another and each surrounded by a gate structure, wherein each channel region of the plurality of channel nanosheets comprises a middle portion and end portions, wherein a thickness of the middle portion is less than a thickness of the end portions, and wherein a width of the middle portion is less than a width of the end portions.

16. The semiconductor structure according to claim 1, further comprising:
stack spacers below and vertically aligned with the plurality of channel nanosheets, wherein a width of the stack spacers measured in a direction parallel to the gate structure is greater than the width of the middle portions of the plurality of channel nanosheets.

17. The semiconductor structure according to claim 15, further comprising:
a backside contact structure self-aligned to shallow trench isolation regions and partially extending beneath the gate structure.

18. The semiconductor structure according to claim 17, wherein a length of a portion of the backside contact structure is approximately equal to a length of a source drain region immediately below and directly contacting the backside contact structure.

19. The semiconductor structure according to claim 17, further comprising:
a placeholder adjacent to the backside contact structure and directly beneath a source drain region.

20. The semiconductor structure according to claim 19, wherein a topmost surface of the backside contact structure is above a topmost surface of the placeholder.
